(19) United States
(12) Patent Application Publication
(10) Pub. No.: US 2020/0328366 A1
(43) Pub. Date: Oct. 15, 2020

(54) HIGH ABSORPTION, PHOTO INDUCED RESONANCE ENERGY TRANSFER ELECTROMAGNETIC ENERGY COLLECTOR

(71) Applicant: Pacific Integrated Energy, Inc., San Diego, CA (US)

(72) Inventors: Phillip Layton, San Diego, CA (US); David Keogh, San Diego, CA (US); Scott Cushing, Glendale, CA (US)

(21) Appl. No.: 16/891,358

(22) Filed: Jun. 3, 2020

Related U.S. Application Data
(63) Continuation of application No. PCT/US2018/064538, filed on Dec. 7, 2018.
(60) Provisional application No. 62/596,531, filed on Dec. 8, 2017.

(51) Int. Cl. H01L 51/44; H01L 51/42

(52) U.S. Cl. CPC H01L 51/447; H01L 51/426

(57) ABSTRACT

Electromagnetic energy collecting devices are described wherein a plasmonic near field resonating system absorbs light and transfers the light energy by plasmonic near field resonance to a semiconducting material that then separates the charge. The charge is then transported out of the device, converting light energy into electrical energy. The multiple nanoparticle plasmonic resonators are closely coupled with an electrically-conductive layer that creates electromagnetic resonances that provide for near perfect absorption of the incoming light. The device can be used both as an optical sensor and as a photovoltaic electromagnetic energy to electrical energy converter.

### CROSS-REFERENCE

This application is a Continuation Application of International Patent Application No. PCT/US2018/064538, filed Dec. 7, 2018, which claims the benefit of U.S. Provisional Application No. 62/596,531, filed on Dec. 8, 2017, each of which is incorporated herein by reference in its entirety.

### BACKGROUND

Traditional inorganic photovoltaics (PVs) use a semiconductor to absorb light, create free-carriers and transport those carriers to generate power. Semiconductors, because of their inherent electron energy level bandgaps, are able to create free charge carriers from absorbed photons. However, because the valence band is nearly full, the semiconductor electrons in the valance band are not mobile and do not respond to the rapidly changing electromagnetic field of visible photons as well as the nearly free conduction electrons found in many metallic materials. These metallic materials are superior to semiconductors for responding to photons with frequencies that fall within the natural linewidth of the plasma resonance of these metals. However, these metals are unable to rectify the rapidly changing electromagnetic field because of the lack of an energy level bandgap or other method to generate one-way current flow. The required thickness for a semiconductor to absorb an adequate amount of light to generate a significant number of free charge carriers is driven by whether it is a direct bandgap or indirect bandgap semiconductor. Crystalline silicon is an indirect semiconductor and typically requires a significantly greater amount of material to absorb enough light to function effectively in a photovoltaic device as compared to a direct band gap semiconductor. The minimum thickness for crystalline silicon is around 100 μm, but most typical production photovoltaic cells are 200 to 500 μm thick. Direct bandgap materials, such as CIGS and CdTe, result in photovoltaic devices that are much thinner, typically in the range of 2 to 3 μm. Increasing the thickness of the semiconductor increases the probability that losses from charge recombination due to material defects will be incurred. Also, the use of thicker semiconductor material generally increases the material cost of the device and, as noted, increases the probability of occurrence of crystalline defects arising from stress or contamination, which then create centers for recombination losses. Since charge transport is through this semiconductor layer, decreasing the thickness may be desirable to lower the overall drift/diffusion distance to increase efficiency. Therefore, it would be desirable to have a photovoltaic that requires a minimal amount of material to absorb the incoming light while using the charge separation advantages of semiconductor materials.

An alternate method to convert light into electric energy is to separate the light absorption and charge separation steps using resonant energy transfer via plasmonic absorption. This method enables the use of high absorption materials and thinner photovoltaic device designs, while using a broader range of semiconductors than are available for use in traditional photovoltaics and sensors. Electromagnetic energy incident on metallic nanostructures can create collective excitations of the conduction electrons, which are called surface plasmons. These plasmons have a finite lifetime and can decay by various methods including radiatively by emitting a photon or non-radiatively by generating electron-hole pairs. They can also transfer their energy to another nearby structure via plasmon induced resonant energy transfer.

Resonance between plasmonic grating structures was shown by Aydin, et al., “Broadband polarization-independent resonant light absorption using ultrathin plasmonic super absorbers,” Nat. Commun., vol. 2, p. 517, 2011. These plasmonic 100 nm thick Ag gratings fabricated on top of a 60 nm thick SiO₂ layer disposed on top of a 100 nm thick layer of Ag created broad visible light resonances and generated absorption that is significantly greater than that for just the plasmonic gratings alone. This improvement in absorption arose from the electromagnetic near field resonance of the top Ag plasmonic grating with the bottom Ag layer. This approach was further improved by Hedayati, et al., “Design of a perfect black absorber at visible frequencies using plasmonic metamaterials.,” Adv. Mater., vol. 23, no. 45, pp. 5410-4, Dec. 2011 and Juluri, et al., U.S. patent application Ser. No. 14/357,941. Hedayati, et al. used a gold composite structure over SiO₂ on top of gold. Juluri, et al. improved on this structure by embedding nanoparticles in a wide bandgap semiconductor such as TiO₂, with a wide bandgap semiconductor spacer and a bottom metal. This device generated a photovoltage by creating hot electrons in the nanoparticles that then were transported out of the metal nanoparticles by a Schottky barrier between the wide bandgap semiconductor and the metal nanoparticles. Near perfect resonance was created by varying the size of the metal nanoparticle interacting in resonance with the bottom metal layer. The difficulty of the Juluri, et al. configuration is that it relied on hot electron transport out of the nanoparticle materials, which limited its efficiency. Hot electron ejection from the nanoparticle has several problems including the high density of states of the metal nanoparticles compared to the surrounding semiconductor, which creates a high probability that the electron will be reabsorbed by the metallic nanoparticle. In addition, it requires a hole transport material adjacent to the nanoparticle to replenish the missing electron, which is difficult because most of the metallic nanoparticles are not adjacent to the hole transport material.

Cushing, et al., “Theoretical maximum efficiency of solar energy conversion in plasmonic metal-semiconductor heterojunctions,” Phys. Chem. Chem. Phys., vol. 17, no. 44, pp. 30013-30022, 2015, showed that putting a thin insulator between the metallic nanoparticle and the semiconductor lengthened the plasmonic dephasing time and improved the plasmon induced resonant energy transfer (PIRET) by limiting interface dampening. The insulator prevents the hot electrons from being transported out of the metallic nanoparticle. This is opposed to hot electron transport across a Schottky barrier as proposed by Juluri, et al. (WO 2013/074542 A1). Here the insulator mitigates hot electron transfer and encourages energy transfer via coherent field energy transfer from dipole-dipole interaction.

While the work from Cushing, et al. focused on single metallic nanoparticle dipole-dipole interaction with a semiconductor, which may provide a slight to moderate improvement in the absorption capabilities of the photovoltaic device, the effect is modest and may not compensate for the added cost associated with the added complexity of introducing nanoparticles into the device. There is accordingly a general need for a method of introducing plasmonic nanoparticles into a photovoltaic device that quite substantially increases the efficiency of the device, while also keeping the cost low.

### SUMMARY

Disclosed herein are devices for collecting electromagnetic energy, comprising: a) a first layer comprised of a plurality of metallic nanostructures each encased in a thin insulating layer, wherein the insulated metallic nanostructures are further embedded in a semiconductor material, and wherein the first layer is adapted to transfer electromagnetic energy from the metallic nanostructures to the semiconductor material via plasmon induced resonant energy transfer; and b) a second layer adjacent to the first layer, wherein the second layer comprises an electrically-conductive material, and wherein the second layer creates a near field electromagnetic resonance with the plurality of metallic nanostructures.

In some embodiments, the device further comprises an optional third layer disposed between the first layer and the second layer, wherein the third layer comprises a semiconductor material that is different from that of the first layer. In some embodiments, the device further comprises a fourth layer in contact with the first layer on a side opposite that of the second or optional third layers, wherein the fourth layer comprises a conductive material that is optically transparent. In some embodiments, an electrical current is generated by the device upon exposure to electromagnetic energy in the ultraviolet, visible, or infrared regions. In some embodiments, the metallic nanostructures comprise a plasmonic resonating core fabricated from Au, Ag, Cu, TiN, Al, Pt, Pd, Ru, Rh, or graphene, or any combination thereof. In some embodiments, the diameter or average dimension of the metallic nanostructures is between about 3 nm and about 60 nm. In some embodiments, the thin insulating layer that encases the metallic nanostructures is comprised of SiO₂, Al₂O₃, TiO₂, a ceramic, a native oxide of the metallic nanostructure core, a polymer insulator, or any combination thereof. In some embodiments, the thin insulating layer that encases the metallic nanostructures is between about 1 nm and about 5 nm in thickness. In some embodiments, the geometry of the metallic nanostructures is spherical, and has an aspect ratio of approximately 1:1. In some embodiments, the geometry of the metallic nanostructures is non-spherical, and has an aspect ratio of greater than 1:1. In some embodiments, the semiconductor material of the first layer comprises Cu₂O, TiO₂, ZnO, CuSbS₂, copper indium gallium (di)selenide (CIGS), Fe₂S, SnS ZnSnP₂2, CuZnSnS₄, CuTaN₂, copper zinc tin sulfoselenide (CZTSSe), perovskites (including organic-inorganic halide perovskite materials), AgBiS₂, silicon, GaN, GaAs, CdTe, an organic semiconductor, or any combination thereof. In some embodiments, the thickness of the first layer is between about 20 nm and about 100 nm. In some embodiments, the first layer further comprises a plurality of semiconductor nanostructures embedded in the semiconductor material. In some embodiments, the plurality of semiconductor nanostructures comprises nanostructures fabricated from one or more semiconductor materials that are different from the semiconductor material of the first layer. In some embodiments, the plurality of semiconductor nanostructures comprises a plurality of quantum dots. In some embodiments, the insulated metallic nanostructures are further coated with an additional outer layer of a semiconductor material that is different from that of the first layer to create core-shell-shell structures that are embedded in the semiconductor material of the first layer. In some embodiments, the second layer comprises Au, Ag, Al, Cu, Pt, Pd, Ti, TiN, ITO, Ru, Rh, graphene, or any combination thereof. In some embodiments, the fourth layer comprises ITO, silver nanowires, graphene, fluorine doped tin oxide (FTO), doped zinc oxide, carbon nanotubes in an organic medium, or any combination thereof. In some embodiments, the third layer comprises Cu₂O, TiO₂, ZnO, CuSbS₂, copper indium gallium (di)selenide (CIGS), Fe₂S, SnS ZnSnP₂, CuZnSnS₄, CuTaN₂, copper zinc tin sulfoselenide (CZTSSe), perovskites (including organic-inorganic halide perovskite materials), MoS₂, WSe₂ or other 2D materials with a formula MX₂ where M is a transition metal and X is a Chalcogen, AgBiS₂, silicon, GaN, GaAs, CdTe, an organic semiconductor, or any combination thereof, and is chosen to be different from the semiconductor material of the first layer. In some embodiments, the third layer is between about 1 nm and about 50 nm thick. In some embodiments, a photoconversion efficiency of the device is greater than 20%. In some embodiments, a photoconversion efficiency of the device is greater than 25%. In some embodiments, a photoconversion efficiency of the device is greater than 30%.

Also disclosed herein are methods for collecting electromagnetic energy and converting it to electrical current, the methods comprising: a) providing the device of any one of claims 1-23; and b) exposing the device to electromagnetic radiation. In some embodiments, the electromagnetic radiation is ultraviolet, visible, or infrared light.

Disclosed herein are systems for collecting electromagnetic energy and converting it to electrical current, the systems comprising: a) providing a plurality of the devices of any one of claims 1-23; and b) exposing the plurality of devices to electromagnetic radiation. In some embodiments, the electromagnetic radiation is ultraviolet, visible, or infrared light. In some embodiments, the plurality of devices comprises at least two devices. In some embodiments, the plurality of devices comprises at least 10 devices. In some embodiments, the plurality of devices comprises at least 100 devices. In some embodiments, the plurality of devices comprises at least 1,000 devices.

### INCORPORATION BY REFERENCE

All publications, patents, and patent applications mentioned in this specification are herein incorporated by reference in their entirety to the same extent as if each individual publication, patent, or patent application was specifically and individually indicated to be incorporated by reference in its entirety. In the event of a conflict between a term herein and a term in an incorporated reference, the term herein controls.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 provides a drawing of one embodiment of the disclosed photovoltaic devices wherein a thin semiconductor separator layer is used.

FIG. 2A provides a drawing of one embodiment of the disclosed photovoltaic devices wherein high aspect ratio nanoparticles are used.

FIG. 2B provides a drawing of one embodiment of the disclosed photovoltaic devices wherein multiple nanoparticle shells are used.

FIG. 3 provides a drawing of one embodiment of the disclosed photovoltaic devices wherein no semiconductor separator layer is used.

FIG. 4 provides a drawing of one embodiment of the disclosed photovoltaic devices that comprises multiple semiconductor nanostructures.

FIG. 5 provides a drawing of one embodiment of the disclosed photovoltaic devices that comprises multiple nanoparticle absorber layers.

### DETAILED DESCRIPTION

The present disclosure describes methods, devices, and systems for efficient coupling of light into electrical energy by using high electron density plasmonic materials to absorb light and then transfer that energy to a charge separating semiconductor material using near field electromagnetic resonances. The disclosed photovoltaic methods and device designs work in two stages. In the first stage, tightly coupled plasmonic resonances are produced in metallic nano-sized structures coupled resonantly to a metallic layer that is in near field proximity to a significant portion of the nanostructures. This enables nearly complete absorption of light across a broad spectrum in a very thin layer of material. A thin insulator layer covers the metallic nanostructures to confine electrons within the metallic nanostructures. Interspersed with, or in close proximity to, the metallic nanostructures is a semiconductor material. Light energy is then transferred to the semiconductor material via resonant energy transfer (RET) by dipole-dipole interactions, or plasmon induced resonant energy transfer (PIRET), which creates free charge carriers in the form of electron-hole pairs. This free charge in the semiconductor is then transported to the two separate electrodes either via a field generated by a p-n junction or the field created by a hole or electron blocking conductive layer.

Also disclosed herein are various device configurations that allow one to adjust and/or optimize the total external efficiency of a light conversion device based on plasmon induced resonant energy transfer (PIRET) coupled to a near field resonant energy absorber. Methods to optimize PIRET are disclosed that use a near perfect plasmonic energy absorbing material that then couples light into a semiconductor material via dipole-dipole interactions between the plasmonic material and the semiconductor while minimizing surface and interface recombination and dephasing of the plasmon caused by hot-electron transfer from the metal nanostructure. Examples of device design parameters that may be adjusted to optimize absorption of electromagnetic energy and overall device photoconversion efficiency include, as will be discussed in more detail below, the number, size, and choice of material for the metallic nanostructures that are embedded in a first semiconductor layer as well as the thickness of the first semiconductor layer, the thickness and choice of material for a thin insulating layer that encapsulates the metallic nanostructures and separates them from the surrounding semiconductor, the optional inclusion of additional semiconductor nanostructures or quantum dots in the first semiconductor layer, the optional use of a thin semiconductor layer that is different from the semiconductor of the “bulk” layer to encapsulate the insulted metallic nanostructures (i.e., to create core-shell-shell structures that are embedded in the semiconductor material of the first layer), the optional use of a thin semiconductor layer disposed between the semiconductor of the first layer and an electrically conductive layer, wherein the optional semiconductor layer is of a different material than that of the “bulk” semiconductor of the first layer, etc. It shall be understood that different aspects of the disclosed methods and devices described herein can be appreciated individually, collectively, or in combination with each other.

Definitions: Unless otherwise defined, all of the technical terms used herein have the same meaning as commonly understood by one of ordinary skill in the art in the field to which this disclosure belongs.

As used in this specification and the appended claims, the singular forms “a”, “an”, and “the” include plural references unless the context clearly dictates otherwise. Any reference to “or” herein is intended to encompass “and/or” unless otherwise stated.

As used herein, the term ‘about’ a number refers to that number plus or minus 10% of that number. The term ‘about’ when used in the context of a range refers to that range minus 10% of its lowest value and plus 10% of its greatest value.

The term “electromagnetic energy,” as used herein, generally refers to electromagnetic radiation (also “light” herein), which is a form of energy exhibiting wave and particle-like behavior. Electromagnetic radiation includes radio waves, microwaves, infrared radiation, visible light, ultraviolet radiation, X-rays and gamma rays. Electromagnetic radiation includes photons, which are the quantum units of electromagnetic interaction and the basic unit of light.

As used herein, the terms “near field electromagnetic resonance”, “near field resonance”, or “near field coupling” refer to the coupling and/or transfer of electromagnetic energy between adjacent structures, e.g., nanostructures or layers of material, that are separated by a distance that is less than a quarter of the wavelength of light corresponding to the electromagnetic energy.

As used herein, the term “plasmon induced resonance energy transfer” or “PIRET” refers to a non-radiative energy transfer mechanism that differs from Förster resonance energy transfer (FRET) in several aspects, including the lack of a Stoke's shift requirement for the directionality of energy transfer, non-local absorption effects, and a strong dependence on the plasmon's dephasing rate and dipole moment.

As used herein, “transparent” or “optically transparent” materials are those materials that transmit all or a portion of any incident electromagnetic radiation, e.g., electromagnetic radiation in the ultraviolet, visible, or infrared regions of the spectrum, or other regions of the electromagnetic spectrum as described above.

Plasmon induced resonance energy transfer (PIRET) as applied to photovoltaics: PIRET for individual particles is described by Cushing, et al. “Progress and Perspectives of Plasmon-Enhanced Solar Energy Conversion,” J. Phys. Chem. Lett., pp. 666-675, 2016. With plasmon induced resonance, when light is first incident on a metallic nanoparticle, the energy is concentrated in a local field, creating a collective oscillation of conducting electrons in the metal to form a plasmon. The plasmon creates a dipole moment that is an order of magnitude higher than that for a surrounding semiconductor. Within approximately 30 to 100 femtoseconds, depending on the metallic nanoparticle, size, shape and material; the plasmon dephases and the plasmon loses its collective behavior. The energy can be: 1) lost to hot electron production in the nanoparticle, 2) dissipated through radiative losses, or 3) transferred into the semiconductor via near field resonant energy transfer at distances typically much less than a quarter wavelength of the incident light.

Near field resonant energy transfer occurs from dipole-dipole coupling between the plasmon and the semiconductor interband transition dipole, transferring energy from the metal into the semiconductor. From Cushing, et al. the resonant energy transfer occurs when the semiconductor is within the plasmon near-field decay length which is approximately 10 nm for visible light. To prevent thermalization, the energy must be coherently transferred to the semiconductor as opposed to undergoing an incoherent Förster resonance energy transfer (FRET) where the energy transfer occurs after a Stokes shift. To prevent further energy transfer from the semiconductor to the metal, the semiconductor must dephase before the metallic nanoparticles plasmon. This will then create an excited electron-hole pair in the semiconductor. This means that the optimum design would have the longest possible metal nanoparticle dephasing time and the shortest possible semiconductor dephasing time. An additional requirement is that there is a spectral overlap between the energy of the plasmon in the metal nanoparticles and the semiconductor band energy.

The size of the nanoparticle affects the energy distribution of hot carriers (e.g., electrons that have very high kinetic energy after being accelerated by a strong electric field in areas of high field intensity within the nanoparticle). The smaller the particle, the more that surface scattering dominates. It has been found that for optical wavelengths and larger nanoparticles of approximately 50 nm in diameter and above, the plasmon frequencies are below the interband transition of gold (2.3 eV) and silver with an interband transition threshold of 3.9 eV, which causes scattering to dominate the light response of the larger nanoparticle, diminishing the strength of the dipole (see, e.g., Cushing, et al. “Theoretical maximum efficiency of solar energy conversion in plasmonic metal-semiconductor heterojunctions,” Phys. Chem. Chem. Phys., vol. 17, no. 44, pp. 30013-30022, 2015). Sönnichsen, et al. further found that as the size of the nanoparticle is reduced to around 15 nm in diameter, the interband damping increases, and as the nanoparticle falls below 3 nm in diameter, the scattering from the increased surface states destroy the collective carrier resonance and the dipole moment (Sönnichsen, et al. “Drastic Reduction of Plasmon Damping in Gold Nanorods,” Phys. Rev. Lett., vol. 88, no. 7, p. 77402, Jan. 2002). Sönnichsen, et al. found that the longest dephasing times were for approximately 20 nm spheres and that nanorods with aspect ratios in the 4:1 range had even longer dephasing times then spheroids of similar sizes.

Novel photovoltaic devices utilizing high absorption, plasmon induced resonance energy transfer: Cushing's work was focused on single metallic nanoparticle dipole-dipole interactions with a semiconductor. The present disclosure describes how to make an electromagnetic energy collecting device using layers of PIRET nanoparticles that achieve a near perfect absorbing configuration. Without the increased absorption achieved through the disclosed configurations, the absorption of individual PIRET nanoparticles would be too small to make a practical photovoltaic device.

The disclosed methods and devices overcome the problems outlined in the Juluri disclosure (that arise from hot electron recombination at the metal interface with the semiconductor and charge conservation) by transferring field energy to the surrounding semiconductor using the PIRET mechanism instead of transferring charge.

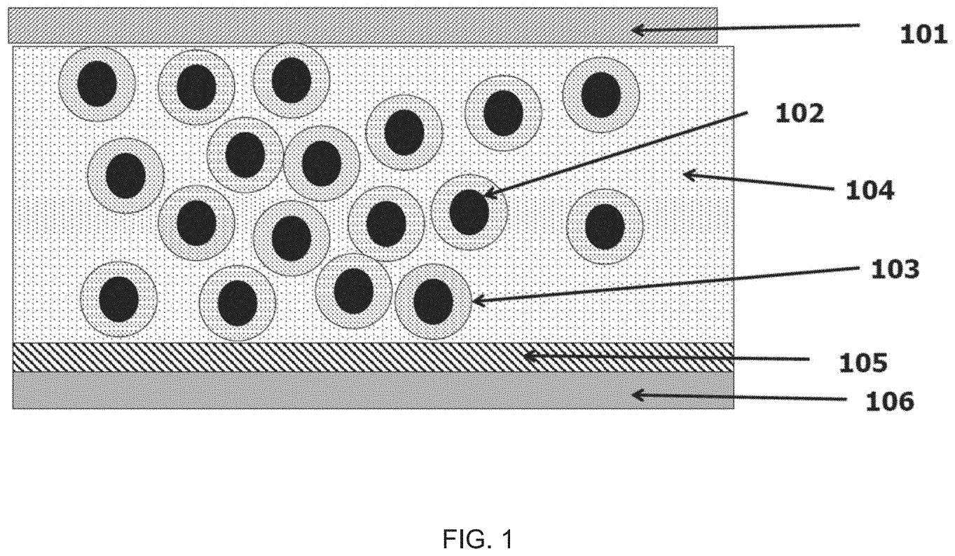

One aspect of the disclosed devices is illustrated in FIG. 1. Light first enters the device through a top layer 101 that is substantially transparent, and in some embodiments, is also preferably electrically conductive. In some embodiments, the electrical conductivity of this layer is mediated by impurities that introduce electron-donor states within the bandgap of the semiconductor material, thus resulting in a material with electron conductivity. Such a layer is typically referred to as an n-type or electron transport layer (ETL). In other embodiments, it may be preferable for layer 101 to have electrical conductivity that is mediated by impurities that introduce electron-hole states within the bandgap of the semiconductor material, thus resulting in a material with p-type or hole conductivity. Such a layer is typically referred to as a hole transport layer (HTL). The use of an electron or hole transport layer in layer 101 is typically aimed at creating a p-n junction diode that is capable of providing an electric field within the device, which improves the transport of the free carriers and increases the device efficiency. In order to create a p-n junction diode, layer 105 must also be electrically conductive, preferably having the opposite conductivity type as layer 101. For example, if layer 101 has n-type conductivity, then layer 105 should have p-type conductivity. Conversely, if layer 101 has p-type conductivity, then layer 105 should preferably have n-type conductivity.

Metallic nanoparticles 102 (also referred to herein as metallic nanostructures) embedded within a semiconductor layer 104 absorb the light both through plasmon generation in near field coupling between the metallic nanoparticles 102 and near field coupling of the electromagnetic energy between the nanoparticles 102 and the bottom metallic electrode 106. The metallic nanoparticles 102 are encased in a thin, insulating layer 103. The coupling is optimized when the distances between the nanoparticles 102 and the bottom metallic electrode 106 is within the near field of the collected electromagnetic wave (i.e., the separation distances are less than the wavelength of the absorbed light). The most efficient coupling is achieved using near field distances of λ/2π (or approximately 0.16 times the wavelength) or smaller. For visible light this distance varies between 64 nm for blue light and 110 nm for red light. This is the maximum separation distance between particles that will enable near field resonance. Each individual plasmonic resonating particle can then be approximated by a short dipole antenna. Using antenna theory, when D<<λ/2, the power radiates as D²/λ were D is the length of the dipole, in this case the size of the metallic nanoparticle 102, and λ is the wavelength of the oscillating dipole or approximately the wavelength of incident light. The closer the particles are to the bottom metallic electrode 106, without touching the bottom electrode, the better the coupling. The distance is then a function of material properties. These properties are dependent on how thin one can make the insulating material 103 without creating pinhole defects. The insulating material 103 should be less than 1/60 of the wavelength of the electromagnetic energy to be absorbed. In the instance of visible light, layer 103 should be less than 10 nm in thickness, but preferably in the range of 1 nm to 4 nm thick.

The interparticle coupling efficiency between the nanoparticles 102 is governed by the 1/R³ decay of the coupling, where R is the distance between the nanoparticles (Girard, et al. “The physics of the near-field,” Reports Prog. Phys., vol. 63, no. 6, pp. 893-938, Jun. 2000). Therefore, the resonant energy transfer between particles is strongest for the most closely proximate particles.

Since PIRET requires dipole-dipole coupling between the metal nanoparticle 102 and the semiconductor 104, the optimum design has the semiconductor closest to the metal nanoparticle. Too many close proximity nanoparticles create additional interaction between the various metal nanoparticles 102, which is counter-productive to transfer of the energy to the semiconductor 104. The optimal nanoparticle density is a balance between the absorption of light by the semiconductor at wavelengths not at the plasmon resonance against the optical density of the plasmon resonance, while also balancing the allowed charge transfer pathways around the nanoparticles with the optical density of the nanoparticles. More specifically, if the density of metallic nanoparticles is too low, then the semiconductor will absorb much of the incident energy and perform similarly to a traditional photovoltaic. In addition, the metallic nanoparticles will be separated by distances that diminish the resonance, and the effect of PIRET will be minimal. On the other hand, having a density of metallic nanoparticles that is too high then leaves too little semiconductor material for efficient absorption of the near field energy. Moreover, because the outer shell of the metallic nanoparticles is insulating, the semiconductor material also serves as the material for transport of the charge carriers to the electrodes, and a high density of metallic nanoparticles will effectively create a high-resistance path that is detrimental to the device performance.

Because the light electromagnetic wave interaction with the metal nanoparticles is evanescent, the particle diameter should be under approximately 60 nm to prevent the interaction being dominated by far-field scattering. Therefore, metal nanoparticle 102 should be approximately 3 nm to 60 nm in diameter.

The metallic nanoparticle 102 (or the plasmonic resonating core thereof) may comprise any metallic or semi-metallic material that has a plasmon resonance in the optical region. Examples of suitable metallic nanoparticle materials include, but are not limited to, gold (Au), silver (Ag), copper (Cu), titanium nitride (TiN), aluminum (Al), platinum (Pt), palladium (Pd), ruthenium (Ru), rhodium (Rh), graphene, or any combination thereof. In some instances, the metallic nanoparticles may also include some heavily doped semiconductors in the infrared. Naik, et al. “Alternative Plasmonic Materials: Beyond Gold and Silver,” Adv. Mater., vol. 25, no. 24, pp. 3264-3294, Jun. 2013, discusses some of these doped semiconductors, examples of which include, but are not limited to, n-Si, p-Si, n-SiGe, n-GaAs, n-GaN, n-InP, Al:ZnO, Ga:ZnO, and (indium tin oxide) ITO. These same materials may be used for the metallic nanoparticles used in any of the device configurations disclosed herein.

For any of the device configurations disclosed herein, the metallic nanoparticles or metallic nanostructures used in the disclosed devices may have any of a variety of shapes known to those of skill in the art. For example, the nanostructures or nanoparticles may be spherical, ellipsoid, rod-like, cubical, triangular plate-like, irregular, or any combination thereof

In some instances, the diameter of the metallic nanoparticles (or average dimension of the metallic nanostructures if not approximately spherical) used in the disclosed devices may range from about 3 nm to about 60 nm. In some instances, the diameter of average dimension may be at least 3 nm, at least 5, nm, at least 10 nm, at least 20 nm, at least 30 nm, at least 40 nm, at least 50 nm, or at least 60 nm. In some instances, the diameter or average dimensions may be at most 60 nm, at most 50 nm, at most 40 nm, at most 30 nm, at most 20 nm, at most 10 nm, at most 5 nm, or at most 3 nm. Any of the lower and upper values described in this paragraph may be combined to form a range included within the present disclosure, for example, in some instances the diameter or average dimension may range from about 5 nm to about 40 nm. Those of skill in the art will recognize that the diameter or average dimension may have any value within this range, e.g., about 22.5 nm. These dimensions or ranges of dimensions apply to the metallic nanoparticles or metallic nanostructures used in any of the device configurations disclosed herein.

The semiconductor layer 104 should match the resonance frequency of the metallic nanoparticle. The optimal semiconductor resonance matches the desired spectrum of light to be absorbed for the typical solar spectrum; for a traditional solar photovoltaic this corresponds to semiconductors with an energy bandgap of between 1.4 eV and 1.5 eV. For the disclosed devices because of the added benefit of the PIRET nanoparticle, the optimum semiconductor bandgap for the solar spectrum at the earth's surface is 1.5 eV to 2.0 eV when coupled to an insulated nanoparticle 103 with a plasma resonance between 1.5 eV to 2.0 eV. However, there are other considerations for choosing the energy bandgap of the semiconductor, for instance, if the device is used in a multi junction or hybrid electromagnetic energy collector then multiple energy bandgap materials may be chosen. In other configurations that may absorb in the infrared, the energy bandgap would have a lower energy.

As an example for a visible light configuration, Cu₂O would have an overlap with Au. Examples of suitable semiconductor materials for layer 104 include, but are not limited to, Cu₂O, TiO₂, ZnO, MoS₂, CuSbS₂, copper indium gallium (di)selenide (CIGS), Fe₂S, SnS ZnSnP₂, CuZnSnS₄, CuTaN₂, copper zinc tin sulfoselenide (CZTSSe), perovskites (including organic-inorganic halide perovskite materials), AgBiS₂, silicon (crystalline, polycrystalline, or amorphous), GaN, GaAs, CdTe, organic semiconductors, any material with a bandgap in the optical or infrared, or any combination thereof. These materials may be used to fabricate the semiconductor layers in any of the device configurations disclosed herein.

In some instances, in order to take advantage of the absorption afforded by the PIRET nanoparticles, the thickness of semiconductor layer 104 may range from about 10 nm to about 120 nm. In some instances, the thickness of semiconductor layer 104 may be at least 10 nm, at least 20 nm, at least 30 nm, at least 40 nm, at least 50 nm, at least 60 nm, at least 70 nm, at least 80 nm, at least 90 nm, at least 100 nm, at least 110 nm, or at least 120 nm. In some instances, the thickness of semiconductor layer 104 may be at most 120 nm, at most 110 nm, at most 100 nm, at most 90 nm, at most 80 nm, at most 70 nm, at most 60 nm, at most 50 nm, at most 40 nm, at most 30 nm, at most 20 nm, or at most 10 nm. Any of the lower and upper values described in this paragraph may be combined to form a range included within the present disclosure, for example, in some instances the thickness of semiconductor layer 104 may range from about 20 nm to about 90 nm. In a preferred embodiment, the thickness of semiconductor layer 104 may range from about 30 nm to about 100 nm. Those of skill in the art will recognize that the thickness of semiconductor layer 104 may have any value within this range, e.g., about 95 nm. These same dimensions or ranges of dimensions may apply to any of the semiconductor layers comprising embedded metallic nanoparticles or metallic nanostructures in any of the device configurations disclosed herein.

In some instances, charge transport layer 105 may be disposed between semiconductor layer 104 and conductive layer 106. This creates a field to enhance charge separation. In some instances, the charge transport layer may be an electron transport layer (ETL). In some instances, the charge transport layer may be a hole transport layer (HTL). The electron transport layer (ETL) can be comprised of, for example, TiOₓ, ZnO, aluminum tin oxides, or any combination thereof The electron transport layer should be thin relative to the semiconductor layer 104. In some instances, a 2D Van der Waals material will such as a MoS₂, WSe₂ or other 2D materials with a formula MX₂ where M is a transition metal and X is a Chalcogen or graphene. In other instances, a thin electron tunneling barrier such as hexagonal boron nitride h-BN may be used. In some configurations the ETL is between 1 nm and 10 nm in thickness. In some cases, it is thicker, e.g., between 5 nm and 40 nm in thickness. In some instances, layer 105 is a hole transport layer (HTL) and can be comprised of materials such as ZnOₓ, NiO, CuSCN and CuI, organic hole transport materials such as 2,2′,7,7′-tetrakis(N,N-di-p-methoxyphenylamine)-9,9′-spirobifluorene (spiro-MeOTAD), MoO₃, or any combination thereof.

As noted above, the thickness of the charge transport layer 105 may range from about 1 nm to about 50 nm, or larger. In some instances, the thickness of the charge transport layer 105 may be at least 1 nm, at least 5 nm, at least 10 nm, at least 20 nm, at least 30 nm, at least 40 nm, or at least 50 nm. In some instances, the thickness of the charge transport layer 105 may be at most 50 nm, at most 40 nm, at most 30 nm, at most 20 nm, at most 10 nm, at most 5 nm, or at most 1 nm. Any of the lower and upper values described in this paragraph may be combined to form a range included within the present disclosure, for example, in some instances the thickness of the charge transport layer 105 may range from about 10 nm to about 30 nm. Those of skill in the art will recognize that the thickness of the charge transport layer 105 may have any value within this range, e.g., about 10 nm. These same dimensions or ranges of dimensions may apply to any of the optional charge transport layers in any of the device configurations disclosed herein.

The thin insulator layer 103 may be any electrical insulator material known to those of skill in the art. Examples include, but are not limited to, SiO₂, Al₂O₃, TiOₓ, ceramic, native oxides of the metallic nanoparticles like silver oxide, a polymer insulator, or any combination thereof. Because of the short plasmon decay length, the thickness of the insulator should preferably be well under 10 nm, and for optimum performance, as thin as possible while still minimizing electron tunneling through the barrier, with typical thickness values of between 1 nm and 5 nm. In some instances, the thickness of the insulator layer 103 may be at least 0.5 nm, at least 1 nm, at least 2 nm, at least 3 nm, at least 4 nm, at least 5 nm, at least 6 nm, at least 7 nm, at least 8 nm, at least 9 nm, or at least 10 nm. In some instances, the thickness of the insulator layer 103 may be at most 10 nm, at most 9 nm, at most 8 nm, at most 7 nm, at most 6 nm, at most 5 nm, at most 4 nm, at most 3 nm, at most 2 nm, at most 1 nm, or at most 0.5 nm. Any of the lower and upper values described in this paragraph may be combined to form a range included within the present disclosure, for example, in some instances the thickness of insulator layer 103 may range from about 2 nm to about 8 nm. Those of skill in the art will recognize that the thickness of insulator layer 103 may have any value within this range, e.g., about 7.5 nm. These same dimensions or ranges of dimensions may apply to any of the insulator layers used in any of the device configurations disclosed herein.

Below the thin semiconductor layer 105 is a bottom conducting layer 106 which preferably forms an ohmic contact with the semiconductor. The bottom conductor layer 106 should be suitable to form a resonance with the metallic nanoparticles 102 to increase absorption. Different combinations of conducting materials can be used for fabrication of the bottom conductor layer 106 including, but not limited to, Au, Ag, Al, Cu, W, Pt, Pd, Ti, TiN, ITO, Ru, Rh, graphene, or hybrid materials containing any combination of the foregoing materials, and other materials. These same materials may be used to fabricate conducting layers in any of the other device configurations described below.

In some instances, the bottom conducting layer 106 may have a thickness ranging from about 10 nm to about 10 microns, or thicker. In some instances, the thickness of bottom conducting layer 106 may be at least 10 nm, at least 50 nm, at least 100 nm, at least 200 nm, at least 300 nm, at least 400 nm, at least 500 nm, at least 600 nm, at least 700 nm, at least 800 nm, at least 900 nm, at least 1 micron, at least 2 microns, at least 3 microns, at least 4 microns, at least 5 microns, at least 6 microns, at least 7 microns, at least 8 microns, at least 9 microns, or at least 10 microns. In some instances, the thickness of bottom conducting layer 106 may be at most 10 microns, at most 9 microns, at most 8 microns, at most 7 microns, at most 6 microns, at most 5 microns, at most 4 microns, at most 3 microns, at most 2 microns, at most 1 micron, at most 900 nm, at most 800 nm, at most 700 nm, at most 600 nm, at most 500 nm, at most 400 nm, at most 300 nm, at most 200 nm, at most 100 nm, at most 50 nm, or at most 10 nm. Any of the lower and upper values described in this paragraph may be combined to form a range included within the present disclosure, for example, in some instances the thickness of bottom conducting layer 106 may range from about 20 nm to about 2 microns. Those of skill in the art will recognize that the thickness of bottom conducting layer 106 may have any value within this range, e.g., about 105 nm. These same dimensions or ranges of dimensions may apply to any of the conducting layers used in any of the device configurations disclosed herein.

In some configurations, the transparent top layer 101 may be a charge transport layer that creates an electric field within the device to improve carrier transport. To create a p-n junction diode, the top layer 101 may be either an ETL or HTL, depending upon the type of layer used in layer 105. For example, if layer 105 is an ETL then layer 101 should be an HTL. Conversely, if layer 105 is an HTL, then layer 101 should be and ETL. Layer 101 may be fabricated from one or more materials including, but not limited to, ITO, silver nanowires, graphene, fluorine doped tin oxide (FTO), doped zinc oxide, carbon nanotubes in organic medium, other conducting transparent or near transparent materials, or any combination thereof. These same materials may be used to fabricate transparent conducting layers in any of the other device configurations described below.

Layer 101 should be relatively transparent, and as such, the choice of material is dependent on the spectrum of the incident electromagnetic radiation and the conductivity of the material. In some instances, the thickness of the transparent electrode 101 may range from about 10 nm up to about 5 microns. In some instances, the thickness of transparent electrode 101 may be at least 10 nm, at least 50 nm, at least 100 nm, at least 200 nm, at least 300 nm, at least 400 nm, at least 500 nm, at least 600 nm, at least 700 nm, at least 800 nm, at least 900 nm, at least 1 micron, at least 2 microns, at least 3 microns, at least 4 microns, or at least 5 microns. In some instances, the thickness of transparent electrode 101 may be at most 5 microns, at most 4 microns, at most 3 microns, at most 2 microns, at most 1 micron, at most 900 nm, at most 800 nm, at most 700 nm, at most 600 nm, at most 500 nm, at most 400 nm, at most 300 nm, at most 200 nm, at most 100 nm, at most 50 nm, or at most 10 nm. Any of the lower and upper values described in this paragraph may be combined to form a range included within the present disclosure, for example, in some instances the thickness of transparent electrode 101 may range from about 30 nm to about 1 micron. Those of skill in the art will recognize that the thickness of transparent electrode 101 may have any value within this range, e.g., about 275 nm. These same dimensions or ranges of dimensions may apply to any of the transparent electrode layers used in any of the device configurations disclosed herein.

Upon exposure to electromagnetic radiation incident on the device, the electromagnetic energy passes through transparent conductive layer 101 and is absorbed either in the semiconductor layer 104 or by nanoparticles 102 and the device generates current. In some instances, greater than 10%, greater than 20%, greater than 30%, greater than 40%, greater than 50%, greater than 60%, greater than 70%, greater than 80%, greater than 90%, greater than 95%, greater than 98%, greater than 99%, or more of the electromagnetic energy incident on the device is absorbed by the nanocomposite layer 104 comprising metallic nanoparticles 102. In some instances, the photoconversion efficiency of the device in any of the configurations disclosed herein may be at least 1%, at least 5%, at least 10%, at least 15%, at least 20%, at least 25%, at least 30%, at least 35%, or at least 40%.

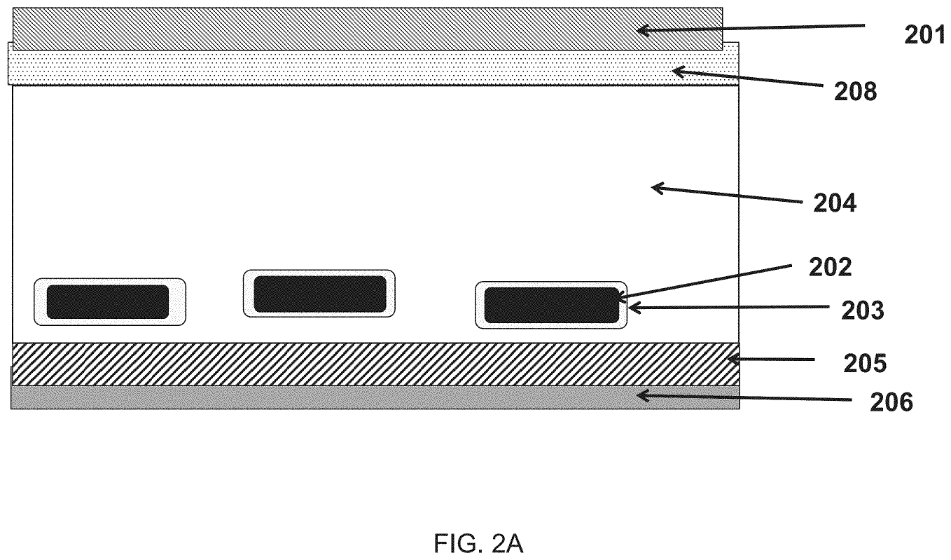

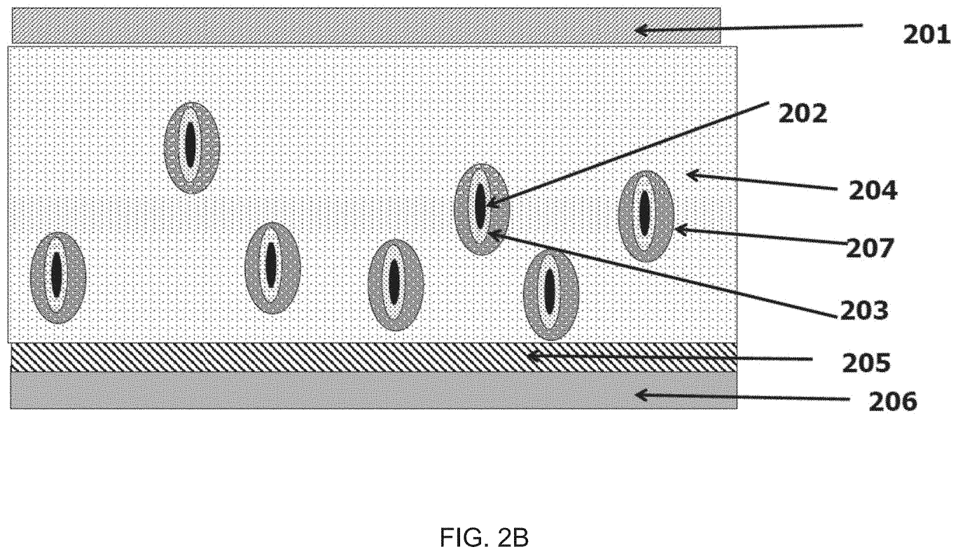

As mentioned earlier, Sönnichsen, et al. found that nanoparticles with higher aspect ratios had longer dephasing times and higher plasmon resonance quality factors; therefore one preferred embodiment would include nanoparticles that have an aspect ratio greater than one. One design is shown in FIG. 2A, in which the metallic nanoparticles 202 are encased with an insulator layer 203 to prevent electron ejection from the metallic nanoparticle. In addition, layer 203 is covered partially or completely by a dipole resonating semiconductor layer 204. In a preferred configuration, a charge transport layer 205 is deposited between semiconductor layer 204 and bottom conducting layer 206. In some cases, the insulating layer 203 may contact charge transport layer 205, which may be a hole transport layer or an electron transport layer. Transparent conductive layer 201 and conductive layer 206 are as described for FIG. 1. In some cases, an optional charge transport layer 208 may be used in conjunction with charge transport layer 205, where if layer 205 is an electron transport layer (ETL) then layer 208 is a hole transport layer (HTL), and vice versa.

The dipole resonating semiconductor is chosen to have a resonance that overlaps the resonance of the metallic nanoparticle 202. To further increase the plasmonic dephasing time for the metallic nanoparticle, the metallic nanoparticle is elongated with an aspect ratio greater than one. Examples of suitable aspect ratios would include 1:1, and ratios up to 1:10. In some instances, the metallic nanoparticles used in this device configuration may have aspect ratios of at least 1:1, at least 1:2, at least 1:3, at least 1:4, at least 1:5, at least 1:6, at least 1:7, at least 1:8, at least 1:9, or at least 1:10.

In another device configuration, called a core-shell-shell configuration, as shown in FIG. 2B, there is an additional semiconductor material 207 that surrounds the insulator shell 203 of the metallic nanoparticles 202. This semiconductor shell 207 is between 5 nm and 30 nm in thickness, and is comprised of a similar material as semiconductor layer 204 (as described above), but can be used to more closely match the plasmon resonance of semiconductor layer 204 while allowing layer 204 to be comprised of a different semiconductor that has fewer defects to transport charge out of the device. The surrounding semiconductor material 204 is chosen to minimize interface traps between the semiconductor material 207 and 204. The surrounding semiconductor material 204 can be the same semiconductor as that used for layer 207, or may be a different semiconductor than that used for layer 207 with a different bandgap. Additional examples of suitable materials for semiconductor layer 204 include Van der Waals 2D materials such as MoS₂, WSe₂, or other 2D materials with a formula MX₂ where M is a transition metal and X is a Chalcogen, graphene, or similar materials. Transparent conductive layer 201, optional charge transport layers 205 and 208 (which may be electron transport layers or hole transport layers), and conductive layer 206 are as described for FIG. 1.

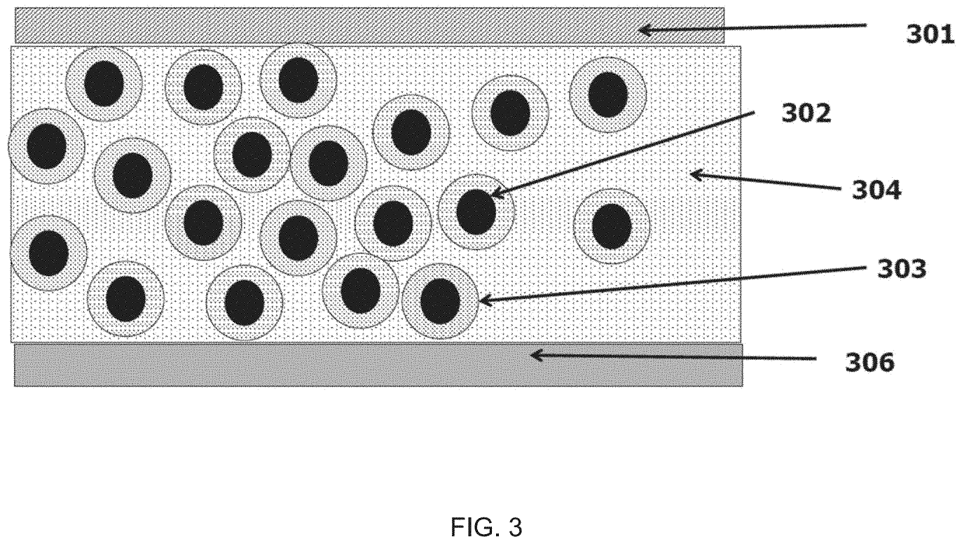

In another device configuration, as shown in FIG. 3, there is no separating semiconductor or charge transport layer corresponding to layer 205 in FIGS. 2A-B. The metallic nanoparticles 302 (encapsulated in insulating layers 303) are embedded in semiconductor layer 304, which is sandwiched between transparent conductive layer 301 and conductive layer 306. This configuration provides for smaller separation distances between the metallic nanoparticles 302 and bottom conducting layer 306, which thus creates a stronger coupling (the separation distances will be on the order of the thickness of the insulator layer 303).

As noted above, the insulator layer 303 may be any electrical insulator material known to those of skill in the art. Examples include, but are not limited to, SiO₂, Al₂O₃, TiO₂ or other ceramic, native oxides of the metallic nanoparticles like silver oxide, a polymer insulator, or any combination thereof. Because of the short plasmon decay length, the thickness of the insulator should preferably be well under 10 nm, and for optimum performance, as thin as possible while still minimizing electron tunneling through the barrier, with typical thickness values of between 1 nm and 5 nm.

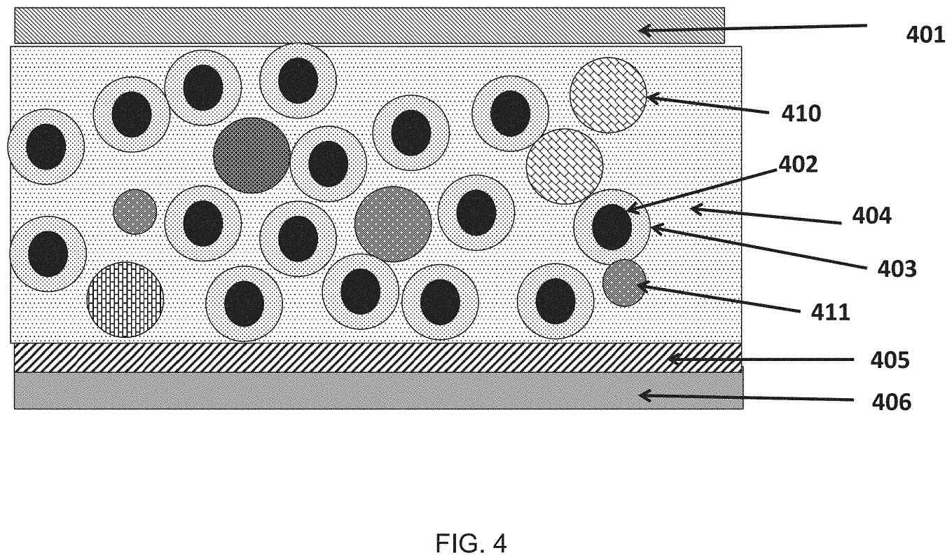

In another device configuration, as shown in FIG. 4, different semiconductors 410 are included in the nanocomposite layer 404 that is sandwiched between transparent conductive layer 401, conductive layer 406, and/or optional charge transport layer 405. This allows light of different wavelengths to couple to the semiconductor with the closest bandgap. Since the semiconductors are still within close proximity to the light absorbing metallic nanoparticles 402 (encapsulated in thin insulating layer 403), the semiconductor that has the closest resonance to the dipole resonance of the metallic nanoparticle 402 will have the highest probability of dephasing with the light energy of the incident photon. Alternative semiconductors that may be incorporated into nanocomposite layer 404 may include any semiconductor material with an appropriate bandgap. Examples include, but are not limited to, silicon, any of the III-V or II-VI semiconductor materials, CuSbS₂, AgBiS₂, CIGS, perovskites (including organic-inorganic halide perovskite materials), etc., or any combination thereof.

Semiconducting quantum dots enable changes in electrical performance as a function of size and shape. For photovoltaic applications, they are limited by their absorption and their high surface to volume ratio, which creates more interface defect states which increase losses from recombination. In one configuration of the disclosed devices, the nanocomposite 404 may comprise quantum dots 411. In this configuration, the device would allow for the use of significantly fewer quantum dots, and hence lower the probability of recombination at surface defects states since the absorption would be in the metallic nanoparticles 402. In this case, all or a portion of the nanocomposite could be comprised of other semiconductors 410 with different bandgaps, thereby creating multiple resonant paths and multiple bandgaps for a multijunction PV cell in a very thin device. The quantum dots may be chosen from any set of materials that have suitable optical bandgaps, such as; II-IV materials or II-VI materials, CdS, CdTe, CdSe, InP, CuInS₂, cesium lead iodide (CsPbI₃), or carbon nanodots. Quantum dots coupled to organic dyes could minimize interface recombination loses.

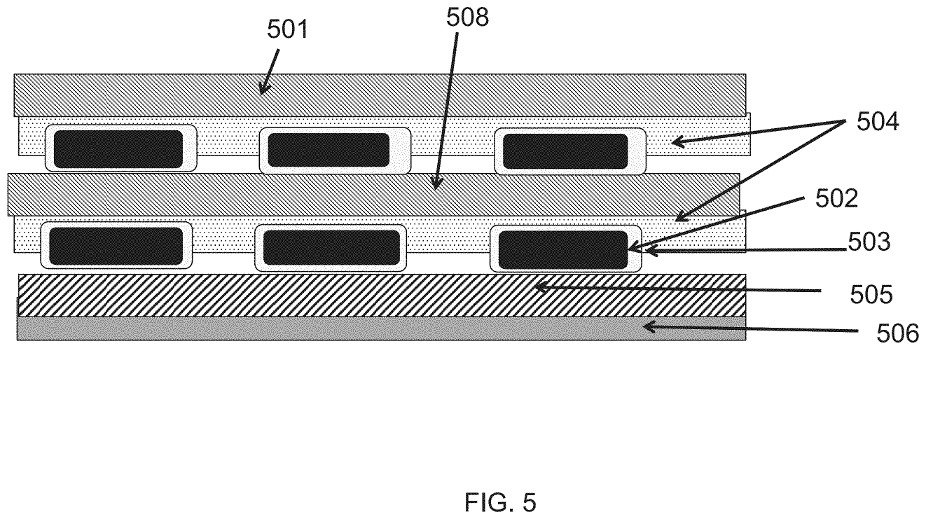

In another aspect of the disclosed devices, as illustrated in FIG. 5, the nanoparticles 502 with insulator shells 503 are deposited in multiple layers that are embedded in semiconductor layer 504 and sandwiched between transparent conductive layer 501, conductive layer 506, and/or optional charge transport layer 505, thereby enabling a multi-bandgap energy collector. This has advantages for device fabrication using deposition processes such as CVD, where the semiconductor 504 can either be deposited with or on top of the insulated nanoparticle. In this configuration, an additional layer 508 may be included that is either conducting (to spread current) or semiconducting (to provide a separate charge collection region). In some instances, layer 508 may be fabricated using the same material as semiconducting layer 504, in which case it is just an additional layer to be deposited during device processing. In some instances, layer 508 may be a 2D Van der Waals material such as MoS₂, or hexagonal boron nitride to create a passivating layer that helps mitigate interface induced defect and trap states. In another configuration, graphene is used for layer 508, thereby separating the top layer and bottom layers and enabling two different semiconductors to be used for layers 504. In some instances, multiple layers (e.g., multiple layers of insulated metallic nanoparticles (502/503) separated by layers 508) are stacked within the same semiconductor layer 504. In some instances, the device may comprise 2 layers of insulated metallic nanoparticles 502/503 separated by 1 layer of 508. In some instances, the device may comprise 3 layers of insulated metallic nanoparticles 502/503 separated by 2 layers of 508. In some instances, the device may comprise 4 layers, 5 layers, 6 layers, 7 layers, 8 layers, 9 layers, 10 layers, or more of insulated metallic nanoparticles 502/503 each separated by a layer 508.

Nanoparticle and device fabrication: The disclosed devices may be fabricated using any of a variety of microelectromechanical (MEMS) and semiconductor processing techniques known to those of skill in the art. Suitable processing techniques will depend heavily upon the choice of materials used within the device, but given the limitations imposed by the need for low-cost manufacturing, it is expected that in many instances the devices will be fabricated using methods amenable to roll-to-roll coating techniques. Methods typically employed in the roll-to-roll manufacturing of thin-film solar cells include, but are not limited to, sputtering, chemical bath deposition (CBD), evaporation and co-evaporation, close spaced sublimation (CSS), chemical vapor deposition (CVD), and plasma-enhanced chemical vapor deposition (PECVD). Though these methods are those that are typically used for fabrication of large-area solar cells, additional processing techniques that are cost-competitive may also be used. Similarly, processing of the various nanoparticles described herein may also be accomplished using a number of different wet-chemical synthesis methods, and will also depend heavily upon the exact choice of materials, size, and geometry, for which extensive literature and a number of commercial vendors exists.

Applications: The disclosed devices may be used as optical sensors and/or as photovoltaic devices for the conversion of electromagnetic energy to electrical energy. In some instances, they may be used as individual, stand-alone sensors or photovoltaic cells. In some instances, multiple devices may be assembled in series or in parallel to create, for example, solar panels for conversion of light energy into electricity. In some instances, these systems may comprise 2 or more of the disclosed photovoltaic devices. In some instances, these systems may comprise at least 10, at least 100, or at least 1,000 of the disclosed photovoltaic devices. The novel methods and device configurations disclosed herein enable the production of low cost, high efficiency electromagnetic energy collector devices.

### Prophetic Examples

These examples are provided for illustrative purposes only and not to limit the scope of the claims provided herein.

One aspect of the methods and devices described herein aims to improve the performance of amorphous silicon p-i-n junction solar cells by improving both the performance and manufacturability. Amorphous silicon (a-Si) solar cells are currently a commercially available technology, though its market share is small (<5%), shrinking, and relegated to niche markets. While amorphous silicon based solar cells are a quite promising technology, as a result of its thin-film form factor, thus far the efficiency of commercial cells is limited to approximately 11%. At the same time, reaching those efficiency values requires slow deposition processes, which limits through-put and increases costs.

The approach described herein could substantially improve the efficiency of amorphous silicon solar cell technology, and in turn improve the manufacturability and cost as well. In particular, the inclusion of metallic nanoparticles that take advantage of PIRET and the resonant cavity structure could significantly decrease the thickness of the amorphous silicon device layers through enhancement in absorption. One of the primary trade-offs in the design of amorphous silicon solar cells is the balance between having a thick enough amorphous silicon to absorb the incident light, while not being too thick so as to lose free charge carriers to recombination at defect sites in the amorphous material. By enhancing absorption and decreasing the thickness of the amorphous silicon, the efficiency could increase substantially, and manufacturing process throughput would increase as a result of the decrease in material to be deposited.

In Cushing, et al., “Theoretical maximum efficiency of solar energy conversion in plasmonic metal-semiconductor heterojunctions,” Phys. Chem. Chem. Phys., vol. 17, no. 44, pp. 30013-30022, 2015, the authors present theoretical calculations that investigate the effects of semiconductor bandgap and plasmon resonant energy, as well as dephasing time and other relevant properties, on the relative expected improvements in photovoltaic conversion efficiency using an embedded metallic nanostructures, without the benefit of a back near field resonance described in this invention. The design of an amorphous silicon solar cell with embedded metallic nanoparticles using PIRET and a resonant cavity as described herein enables a higher conversion efficiency, as is presented below.

Amorphous silicon-based solar cells have a bandgap of approximately 1.6-1.9 eV. In order for optimum energy transfer to occur from the plasmon to the semiconductor, the energy of the plasmon must partially overlap the bandgap energy of the semiconductor, with the optimum transfer occurring at exactly or slightly less than the semiconductor bandgap energy. For example, for amorphous silicon with a bandgap of 1.9 eV, the optimum energy transfer would occur for plasmon energies of approximately 1.8-1.9 eV. Most semiconductor materials, however, being crystalline in nature, have a very well defined bandgap, with a very low density of states at energies just below the bandgap (10 milli-electron volts or less). Coupling between metallic nanoparticles and the semiconductor via PIRET is therefore inefficient. Amorphous silicon, on the other hand, because of its amorphous nature with a large density of defect states, has a relatively large density of states for electrons within about 100 milli-electron volts, known as the Urbach tail. The Urbach tail refers specifically to the states just below the semiconductor conduction band (typically within 40-50 milli-electron volts) and just above the semiconductor valence (also typically within 40-50 milli-electron volts). Because PIRET is efficient at coupling to the states at or below the semiconductor bandgap, coupling to amorphous silicon is much more efficient than other semiconductors, and effectively extends the energy range over which the amorphous silicon is able to absorb.

With the bandgap of amorphous silicon materials used in solar cells typically in the range of 1.6 to 1.9 eV, and the need for spectral overlap with the energy of the plasmon to be at or below this bandgap energy, this implies that the energy of the plasmon should approximately be in the range of 1.5 to 1.8 eV. Based on the required energy range for the plasmon, certain materials and geometries for the metallic nanoparticles may be preferred. While the metallic core material, insulator shell material, and overall nanoparticle geometry could be any of a large number of possibilities, certain combinations are readily known to satisfy the design requirements. In particular, metallic cores of gold or silver with a silica (SiO₂) shell are readily commercially available in spherical, rod, or plate-like geometries, and provide plasmon energies in the desired range of 1.5-1.8 eV. Nanoparticles with a rod-like geometry may be the preferred geometry when the dephasing time is taken into consideration. The preferred thickness of the SiO2 insulator shell should be as thin as possible to maximize energy transfer to the semiconductor, while also being thick enough ensure complete surface coverage of the metallic nanoparticle. Preferably this thickness would be in the range of 1-3 nanometers, but may be as thick as 10-20 nanometers to account for processing non-uniformities.

With the nanoparticle design above, an amorphous silicon solar cell is able to take advantage of energy transfer via PIRET, potentially leading to substantial improvements in absorption and also energy conversion efficiency. The expected improvement from the disclosed devices as compared to a traditional amorphous silicon PV cell would be over 2×. The resonator cavity would further improve the absorption properties of the amorphous silicon and also the energy conversion efficiency. With current amorphous silicon solar cells at 11% or less, it could be expected that the energy conversion efficiency could be greater than 22%.

An amorphous silicon solar cell that incorporates energy transfer via PIRET coupled to a resonator cavity design may have a substantially thinner layer of amorphous silicon within the device. Current commercially-available amorphous silicon solar cells utilize a layer of approximately 350 nm for absorption of incident energy; this could be reduced down to 100 nm or less, perhaps as low as 50 nm or less, using the approach described herein. A thinner layer of amorphous silicon would substantially improve the conversion efficiency, since the distance traveled by free charge carriers is shorter, and therefor reduces the probability of recombination events.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in any combination in practicing the invention. It is intended that the following claims define the scope of the invention and that methods and structures within the scope of these claims and their equivalents be covered thereby.

1. A device for collecting electromagnetic energy, comprising:
a) a first layer comprised of a plurality of metallic nanostructures each encased in a thin insulating layer, wherein the insulated metallic nanostructures are further embedded in a semiconductor material, and wherein the first layer is adapted to transfer electromagnetic energy from the metallic nanostructures to the semiconductor material via plasmon induced resonant energy transfer; and
b) a second layer adjacent to the first layer, wherein the second layer comprises an electrically-conductive material, and wherein the second layer creates a near field electromagnetic resonance with the plurality of metallic nanostructures.

2. The device of claim 1, further comprising an optional third layer disposed between the first layer and the second layer, wherein the third layer comprises a semiconductor material that is different from that of the first layer.

3. The device of claim 1, further comprising a fourth layer in contact with the first layer on a side opposite that of the second or optional third layers, wherein the fourth layer comprises a conductive material that is optically transparent.

4. The device of claim 1, wherein an electrical current is generated by the device upon exposure to electromagnetic energy in the ultraviolet, visible, or infrared regions.

5. The device of claim 1, wherein the metallic nanostructures comprise a plasmonic resonating core fabricated from Au, Ag, Cu, TiN, Al, Pt, Pd, Ru, Rh, W, graphene, or any combination thereof.

6. The device of claim 1, wherein the diameter or average dimension of the metallic nanostructures is between about 3 nm and about 60 nm.

7. The device of claim 1, wherein the thin insulating layer that encases the metallic nanostructures is comprised of SiO₂, Al₂O₃, TiOₓ, a ceramic, a native oxide of the metallic nanostructure core, a polymer insulator, or any combination thereof.

8. The device of claim 1, wherein the thin insulating layer that encases the metallic nanostructures is between about 1 nm and about 5 nm in thickness.

9. (canceled)

10. The device of claim 1, wherein the geometry of the metallic nanostructures is non-spherical and has an aspect ratio of greater than 1:1.

11. The device of claim 1, wherein the semiconductor material of the first layer comprises Cu₂O, TiO₂, ZnO, CuSbS₂, copper indium gallium (di)selenide (CIGS), Fe₂S, SnS ZnSnP₂, CuZnSnS₄, CuTaN₂, copper zinc tin sulfoselenide (CZTSSe), perovskites (including organic-inorganic halide perovskite materials), AgBiS₂, silicon, GaN, GaAs, CdTe, an organic semiconductor, or any combination thereof.

12. (canceled)

13. The device of claim 1, wherein the first layer further comprises a plurality of semiconductor nanostructures embedded in the semiconductor material.

14.-16. (canceled)

17. The device of claim 1, wherein the second layer comprises Au, Ag, Al, Cu, Pt, W, Pd, Ti, TiN, ITO, Ru, Rh, graphene, or any combination thereof.

18. The device of claim 3, wherein the fourth layer comprises ITO, silver nanowires, graphene, fluorine doped tin oxide (FTO), doped zinc oxide, carbon nanotubes in an organic medium, or any combination thereof.

19. The device of claim 2, wherein the third layer comprises Cu₂O, TiOₓ, ZnO, MoS₂, WSe₂, CuSbS₂, copper indium gallium (di)selenide (CIGS), Fe₂S, SnS ZnSnP₂, CuZnSnS₄, CuTaN₂, copper zinc tin sulfoselenide (CZTSSe), perovskites (including organic-inorganic halide perovskite materials), AgBiS₂, silicon, GaN, GaAs, CdTe, an organic semiconductor, aluminum tin oxides, 2D materials with a formula MX₂ where M is a transition metal and X is a Chalcogen, graphene, hexagonal boron nitride h-BN, MoO₃, NiO, or any combination thereof, and is chosen to be different from the semiconductor material of the first layer.

20. The device of claim 2, wherein the third layer is between about 1 nm and about 50 nm thick.

21.-23. (canceled)

24. A method for collecting electromagnetic energy and converting it to electrical current, the method comprising:
a) providing the device of claim 13; and
b) exposing the device to electromagnetic radiation.

25. (canceled)

26. A system for collecting electromagnetic energy and converting it to electrical current, the system comprising:
a) providing a plurality of the devices of claim 1; and
b) exposing the plurality of devices to electromagnetic radiation.

27. The system of claim 26, wherein the electromagnetic radiation is ultraviolet, visible, or infrared light.

28-30. (canceled)

31. The system of claim 26, wherein the plurality of devices comprises at least 1,000 devices.
